(19) United States
(12) Patent Application Publication
(10) Pub. No.: US 2020/0007127 A1
(43) Pub. Date: Jan. 2, 2020

(54) CAPACITIVE SENSOR SWITCH WITH DISPLAY

(71) Applicant: CAPTRON Electronic GmbH, Olching (DE)

(72) Inventors: Reinhard Bellm, Germering (DE); Kilian Hüttenhofer, München (DE)

(21) Appl. No.: 16/569,079

(22) Filed: Sep. 12, 2019

Related U.S. Application Data
(63) Continuation of application No. PCT/EP2018/056261, filed on Mar. 13, 2018.

(30) Foreign Application Priority Data
Mar. 13, 2017 (EP) 17160601.5

(51) Int. Cl. H03K 17/96; G06F 3/044

(52) U.S. Cl. CPC H03K 17/962; H03K 2217/960785; H03K 2217/960755; G06F 3/044

(57) ABSTRACT

A capacitive sensor switch with a housing and a sensor assembly. The sensor assembly includes a printed circuit board holding a sensor circuit with multiple LED and a cover disk located on the printed circuit board and oriented towards the front side of the switch. The cover disk has an electrically conductive surface connected to the sensor circuit and a plurality of light channels for guiding the LED light.

### CROSS-REFERENCE TO RELATED APPLICATIONS

This application claims priority from pending European Application No. 17160601.5 filed on 13 Mar. 2017.

This application is also a continuation of pending International Application No. PCT/EP2018/056261 filed on 13 Mar. 2018, which designates the United States and claims priority from the European Application No. 17160601.5 filed on 13 Mar. 2017. The disclosure of each of the above-identified applications is incorporated herein by reference.

### BACKGROUND

### 1. Field of the Invention

The invention relates to a capacitive sensor switch with an integrated display unit and to a consignment system (also referred to as a pick to light system) that employs such a sensor switch.

### 2. Description of Relevant Art

In GB 1 464 095, an input and display unit is disclosed. Input of setpoint values is carried out by sensor switches of a sensor surface with the functions “upwards”, “downwards”, and “off”. A 7-segments display is arranged besides the sensor surface for displaying the preset value.

U.S. Pat. No. 6,685,031 B2 discloses a display unit for a consignment system, wherein a mechanical check button is arranged in addition to a 7-segment display.

### SUMMARY

The embodiments provide an input and output unit for use with a consignment system (also known as a pick to light system), which is robust, easy to mount, and easy to operate. A further aspect of the embodiments is the design of a consignment system with a corresponding input and output unit (or user interface).

In one embodiment, an input and output unit serving as a user interface includes a capacitive sensor switch with an integrated display unit, configured to display letters and/or digits. Generally, sensor switches are switching elements that deliver signal(s) upon being touched, preferably with a finger or a hand. Such signal(s) has in general the information content of 1 bit, i.e. the signal is mostly an “on/off” signal. Here, sensor switches differ significantly from touch-sensitive screens used as monitors or display in Smartphones. In the latter case, a sensor signal formed as an output by the touch sensor of a touch-sensitive screen is, in general, a high-resolution position signal that enables the process of location, as accurately as possible, of one or more fingers resting on the screen. For this purpose, a complex and filigree sensor technique is necessary. In comparison, the sensor switch of the former, as disclosed herein, can be designed with substantial simplicity, as the presence of only one finger has to be recognized and/or displayed.

With respect to robustness, there are significant differences between a switch being generally used in an industrial and/or commercial fields, and a touch-sensitive screen. A switch must withstand strong impacts or shocks without being damaged. Furthermore, a switch is often exposed to unfavorable environmental conditions such as high air humidity, or high and/or low temperatures. For this reason, switches are often manufactured with stainless steel housings. In comparison, touch-sensitive screens and, in particular, displays of Smartphones are normally treated very carefully. In order to reach a high degree of local spatial resolution, the distance from the sensor to the finger (i.e. inter alia the thickness of the glass there-between) should be as small as possible. This requirement causes and results in a significantly lower mechanical stability as compared to a switch. In a consignment system, it might occur that a heavy object falls on a switch: the design of the switch should accommodate such possibility and prevent the damage to the switch. In comparison, typically such a situation does not occur with a mobile phone.

The sensor switch preferably does not include mechanically movable parts. Thus, the sensor switch may be integrated into a completely closed housing and, therefore, may be configured to be water-proof. The housing has a front side (through which the switch may be operated) and an opposing rear side (through which the switch may be mounted and/or which may hold electrical connectors).

A capacitive sensor switch contains a housing with a front side and a rear side. The front side is the sensor side through which the switch is operated and by which it displays information to the user, while the rear side may be a mounting side (that is, a side configured for mounting the switch onto an appropriate surface). A particular embodiment of a switch re may be made double-sided, so there is a sensor located at the rear side.

The sensor switch may include a sensor assembly, which in turn includes a printed circuit board (PCB) and a cover disk. The PCB may have at least one sensor area that may be connected to a sensor circuit. The cover disk may be on the printed circuit board and may be oriented towards the front side. It is preferred that the switch have a sensor surface that is as large as possible, for the switch to possess a high sensitivity and be able to identify a finger in a glove. A single sensor or a differential sensor may be provided in order to achieve better sensitivity and/or better suppression of interference signals.

For displaying various information (in particular—a number of pieces that should be taken from or put into a container during a particular processing operation, for example) an embodiment can be provided with a display. This display is preferably a simple display with high brightness and great contrast, for example a 7-segment LED (Light Emitting Diode) display or a segment display with another number of segments, for example 9, 14, or 16 segments, or a dot matrix display. This display may be configured to display information in different colors. When so-arranged, an embodiment of the consignment system employing the switch allows several persons, each person with its individually assigned color, to simultaneously operate the consignment system. The same applies to the configuration employing the LED outer ring (which is preferably based on RGB LEDs and which enables the client to display individual colors for the consigner or for operating states). Preferably, the LEDs of the LED outer ring are arranged on the PCB.

In one implementation, the display may be integrated into the sensor area. That means that touching the display, in operation, may trigger a switching activity of the switch. Thus, the switch may be embodied to be more compact, as no adjacent operation or display surfaces are necessary. Furthermore, in this case the sensor surface may be designed to be larger than in an otherwise case.

Furthermore, there is a sensor circuit and a sensor area electrically connected to the sensor circuit, preferably on the PCB. The sensor circuit may detect the presence of a conductive object, for example a finger or a hand in close proximity to the sensor area. The detection distance may be in a range from 0 mm (directly on the sensor area) to 30 mm above or in front of the sensor area. In related embodiments, such detection distance may be defined within the spatial range from 0 mm to 10 mm, or from 0 mm 5 mm. For appropriate detection, in operation an electric signal such as a HF or RF signal may be fed into the sensor area, and change(s) of the level of such signal caused by capacitive coupling to the object may be further evaluated. The sensor area may comprise multiple spatial sections, in one non-limiting implementation—into radially-arranged sections. An inner section may be configured as a main sensing section, while surrounding section(s) of the sensor area may be configured as guard(s) or reference section(s).

In one implementation, the cover disk may be configured to incorporate a dielectric material (such as a plastic material, for example). Such dielectric material, when used, serves to improve coupling of the electric field from the sensor area to the object.

Preferably, the cover disk has an electrically-conductive surface. The cover disk may also optionally contain, for example, metal (in one case—a metallic foil), a plastic part having a metallized surface, or a plastic part that includes electrically-conductive particles. When present, the electrically-conductive surface of the cover disk may also be dimensioned to be thicker than a foil or, respectively, may have appropriate structural reinforcements appropriately configured to employ this surface as a mechanical protection for the display located behind this surface. In front of the electrically-conductive surface of the cover disk, a protective panel (in particular—the one containing polycarbonate) may be additionally disposed. Depending on the embodiment, the cover disk may have a thickness in a range from 0.5 to 8 mm, preferably between 1 mm and 3 mm. The thickness of the cover disk may be constant across the disc (not considering the structural channels, pins and recesses). The disk may have a contour dimensionally adapted to the shape of the sensor switch. For example, the cover disk may be round in shape and may have a diameter with a value chosen between 30 and 80 mm. Optionally, the cover disk may be capacitively coupled or galvanically connected to the sensor area and/or the sensor circuit.

An embodiment of the cover disk is further configured to provide a plurality of light channels (for example, through-holes) to guide light from the at least one LED to the front side of the switch. Such light channels may be empty (hollow) channels or spaces within the cover disk, and have sidewalls of the cover disk's material. At least one of the LEDs may be disposed within the light channel(s), or even slightly below the level of the light channels if there exists a gap between the cover disk and the PCB. The sidewalls of the channels may also have a light-colored (for example, white-colored) and/or mirrored/reflective surface. Additionally or in the alternative, such channels may also be filled with an optically transparent material.

Alternatively or in addition, there may be added an optical sensor, e.g. a photodiode, in/to at least one of the light channels of the cover disk. Such optical sensor may be disposed alone, by itself, or in combination with a LED in a light channel. In operation, the optical sensor is configured and may be used to detect the presence of various objects (e.g. a finger or a hand) present above the channel. Therefore, the optical sensor cooperated with the cover disk may be configured and/or used as an optical proximity sensor. In a specific implementation, such optical sensor is configured to possess high spatial resolution (similar to that of a capacitive sensor) and therefore is used to allow for detection of a specific position/location (e.g. a digit or ring segment) at the disk to be touched. Furthermore, in one embodiment the reliability of the detection process may be improved by correlating optical and capacitive signal detection methodologies.

An embodiment of the switch may be complemented with a simple switching output circuitry, for example the one configured to produce a voltage impulse, and/or with a switching contact (for example, a relay contact). It is preferred, however, if the switch includes or is cooperated with a network and/or a bus interface. Said interface may be an RS485 interface, in one example.

The use of a bus interface in an embodiment of the invention serves the purposes of interconnecting a plurality of switches with one another and/or with a control unit. The embodiment of the switch may be controlled and/or be parameterized via the bus interface. For example, the selection of a switching function of the switch (a press function, a switching function or a static activation) may be effectuated in such a case, and/or numeric values and/or letters (preferably also a ticker) may be utilized and controlled. Furthermore, additional display functions, for example color selection, flashing, different brightness grades, or a timely variable display may be appropriately configured for operation with the use of the interface.

The display of an embodiment of the switch may also include additional display elements, such as dots or at least one circle or circular arc area(s) dimensioned to be circumferential at the edge of the switch. Optionally, such a circle or arc may be divided into several segments, so that the complete circle and/or its segments are controllable with the use of the interface. Besides the above-described controlling functions, the circle area may also represent (be configured as) a circumferentially-shaped display portion. The terms “digit display” or “digital display” are used for simplicity of presentation, although such display(s) are intended in general to display digits, numbers, letters, and/or other symbols. Therefore, multiple LEDs are arranged, in an embodiment, such as to form, in operation, a representation of at least a digit or a number or a letter or a circle or a section thereof.

An embodiment of the switch may be configured to have a wireless interface. In one example, such an interface may be an NFC interface (Near Field Communication), which could for example operationally implement one of the standards SO/IEC 13157, -16353, -22536, -28361.

Thus, a communication of an embodiment of the switch with a smartphone may be made possible. In this way, various settings may be configured. When used in a logistics system, the position of the person at (in reference to) the embodiment of the switch could thereby be detected. An authentication procedure may additionally be carried out. Furthermore, the collected information/data representing which person has operated which switch can be detected and appropriately stored in a tangible storage memory device.

An embodiment of the switch may additionally include appropriately-configured means for detecting gestures. For example, an indicated numeral value may be changed by simple gestures. An example of such a gesture is provided by a motion of a finger from left to right in order (e.g., to increase the numeral value at the switch), or from right to left (to reduce the numeral value). For the evaluation of the gestures with an embodiment of the invention, it is not necessary to implement a complex touch-sensitive display (such as done, for example, in Smartphones). Here, the sensor in the switch of the embodiment must be robust, simple and reliable. To recognize a movement in two directions, the overall sensor surface can be spatially sub-divided only in two or four smaller sensor surfaces, which proves to be operationally sufficient. In the case of a round-shape sensor switch, for example, the two sensor surfaces could be dimensioned to be semicircular with a vertical division. In this example, at first the left sensor surface detects the presence of a finger of the user, and later the finger is detected by both sensor surfaces simultaneously, and later yet is detected only by the right sensor surface, the motion could be recognized and assessed as the motion over the sensor device from left to right. In this way, different simple gestures may be detected with sufficient precision. The entry of information about numerals or simple letters into the device is, therefore, effectuated in a simple way by simply drawing such letters and numerals onto the surface of the sensor with a finger.

An embodiment of the consignment system may be configured to include several capacitive sensor switches with an integrated display, as described herein. These may be connected to one another as well as to a control unit. The switches may preferably be connected in series with other switches in order to keep the cabling as short as possible, which provides a significant advantage especially with larger systems.

A related embodiment addresses a method for operating a consignment system. Here, several sensor switches of the consignment system may be operationally assigned to or associated with different goods containers, trays, or goods storage places. According to a consignment order, the control unit controls the displays of the sensor switches in such a way that a number, a mass, or another unit of the goods to be consigned is indicated. A person (user) compiling or distributing the goods may easily recognize—with the help of the display of the sensor switch—which goods are needed or to be picked in which quantity, or which goods are to be put in which storage place. As soon as the corresponding quantity of goods is provided, the person may touch the surface of the sensor switch for acknowledgement, or may perform a certain gesture on the surface. As soon as the sensor switch detects this action, the sensor switch may generate a signal to the control unit. In this way, the control unit follows up the execution of the order.

In further embodiments, the indicated number or quantity may be changed on the sensor switch for example by touching certain partial surfaces or by gestures. This may be transmitted to the control unit. Thereby, changed quantities or also shortfalls may be registered. In addition, an identification or authentication of the person may be conducted via NFC, for example by a mobile phone or mobile data entry (MDE) device held against the sensor switch.

### BRIEF DESCRIPTION OF THE DRAWINGS

In the following, the invention will be described by way of example, without limitation of the general inventive concept, on examples of embodiment and with reference to the drawings.

FIG. 1 shows a front view of a capacitive sensor switch.

FIG. 2 shows an embodiment from the rear side FIG. 3 presents a sectional side view of an embodiment.

FIG. 4 addresses details of the sensor assembly.

FIG. 5 provides a further sectional view of the sensor assembly.

FIG. 6 illustrates an enlarged section of the ring display.

FIG. 7 shows the interior of a ring channel in more detail.

FIG. 8 provides details of a cover disk.

FIG. 9 shows a PCB.

FIG. 10 schematically illustrates an embodiment of a sectioned cover disk.

FIG. 11 shows a further sectioned cover disk.

FIG. 12 shows a consignment system.

FIG. 13 is a flow chart of a method of operating a consignment system.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION

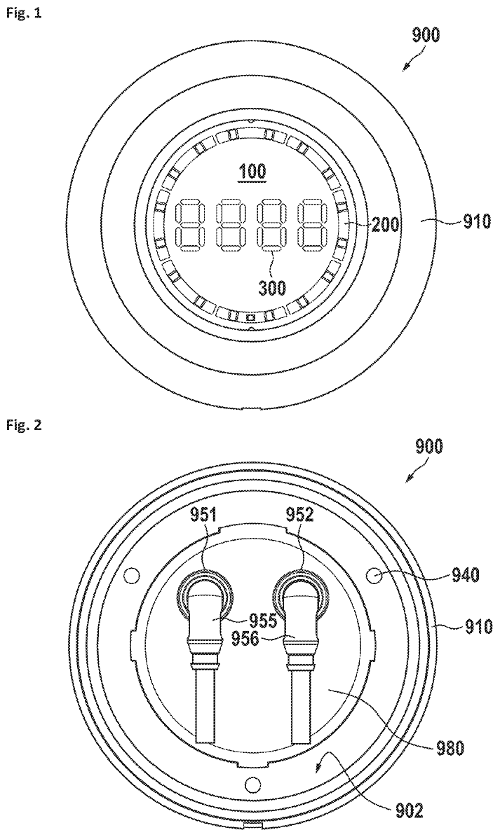

In FIG. 1, a front side 901 of a capacitive sensor switch 900 of an embodiment is shown. The sensor switch includes a housing 910, which further includes a sensor or sensor assembly 100. A ring-shaped display 200 and a digit display 300 of the sensor assembly are shown. There may be any other types of display and any combination thereof.

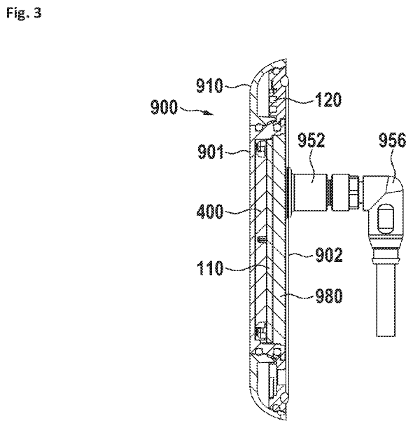

In FIG. 2, an embodiment of the sensor switch 900 as seen from the rear side 902 is shown. There may be fixation means 940, for example screw holes which may either be configured for self-tapping screws or may have a thread. Furthermore, there may be connectors for connecting a power supply and/or a bus or a network. It is preferred to have two connectors as shown in this example to allow daisy chaining of a bus. There may be a first bus connector 951 for a first cable connector 955 and a second bus connector 952 for a second cable connector 956. The rear side may either have a cover or may comprise a casting compound 980. It is preferred, if the interior of the housing, but preferably not the light channels, is filled with a casting compound.

In FIG. 3, a sectional side view of an embodiment of a capacitive sensor switch 900 is shown. It is a vertical section at the center of FIG. 1. Here, the details of the sensor assembly are shown. A printed circuit board (PCB) 110 may hold or carry thereat a sensor circuit 120. A cover disk 400 may be mounted on top of the printed circuit board. Preferably, the cover disk shows a space between the printed circuit board 110 and the housing 910.

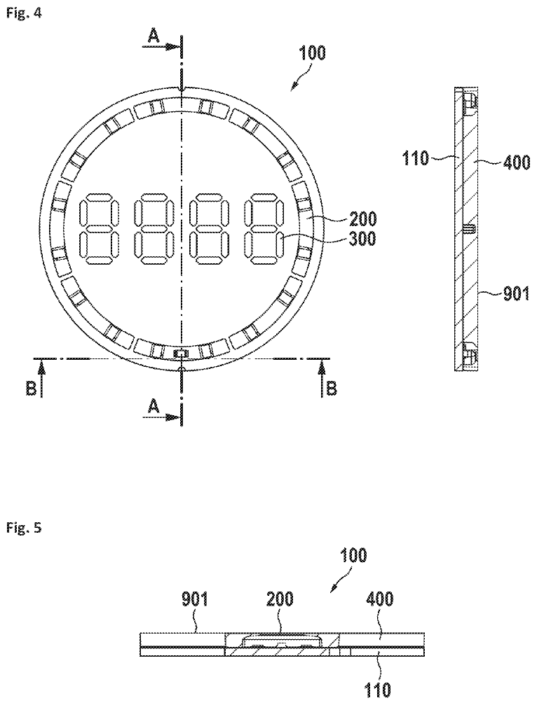

In FIG. 4, details of the sensor assembly 100 are shown in a front view as seen from the front side 901 at the left part of the figure. The right part of the figure shows a sectional view as marked by the letters A-A. The ring display 200 comprises a plurality of ring segments—in this embodiment there are eight segments—which may be illuminated by LEDs. The digit display 300 comprises a couple of digits, for example 4 digits. In this embodiment, 7-segment digits are shown, wherein the individual segments of the digits may be illuminated by LEDs to display desired digits (and/or letters and/or numbers).

In FIG. 5, a further sectional view of the sensor assembly 100 along the line B-B is shown. The section of the ring display 200 is shown enlarged and with more detail in the following Figures.

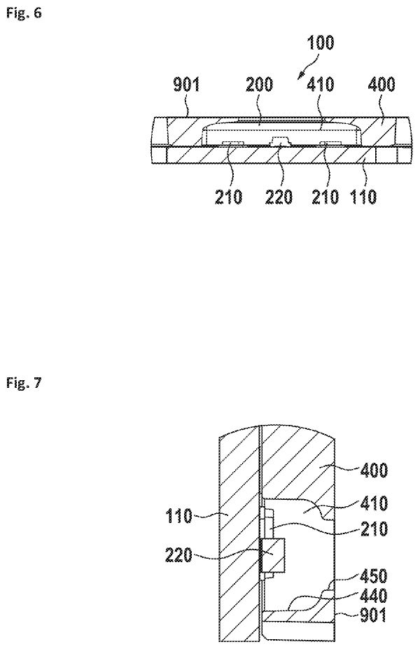

In FIG. 6, an enlarged section of the ring display 200 is shown. Here a section of a ring channel 410 is shown enlarged. Basically, any of the ring light channels 410 and the digit light channels 420 may be built as described herein.

On the PCB 110 and within the ring light channel 410, there is at least one LED 210. In this embodiment, two LEDs are shown to increase light intensity and to improve light distribution over the length of the channel. Basically, any number of LEDs may be used in a channel. The LEDs may be single color or multicolor types such as RGB LEDs or a combination thereof. Furthermore, an optical sensor such as a photodiode 220 may be provided. This photodiode may be an infrared diode or any other suitable diode, photo-transistor or integrated sensor. It may be used to detect the presence of any object, such as a finger or a hand above the channel. Therefore, the optical sensor may be or may be used as an optical proximity sensor. Such an optical sensor may be used to detect the presence of a finger above one of the ring channels with a higher resolution than the capacitive sensor. Furthermore, the reliability of detection may be improved by correlating optical and capacitive signal detection. Depending on the presence of a finger above a ring channel, the reflective properties are changed, and therefore the photo diode 220 receives a different amount of light which may either be ambient light or light from the LEDs. Such a difference in light may be detected and evaluated to generate a control signal. Preferably such a photo diode is coupled to the sensor circuit 120.

In FIG. 7, the interior of a ring channel 410 is shown in more detail in a side view. Basically, the digit light channels 420 are built the same way. Here, an LED 210 is shown besides or behind a photodiode 220. Each channel has at least one inner wall 440 which may have reflective properties. At the outer end (distant from the LED and the PCB) there is an edge 450 which defines the contour of a symbol to be displayed. The contour may either be a segment of the ring display or a segment of the digit display.

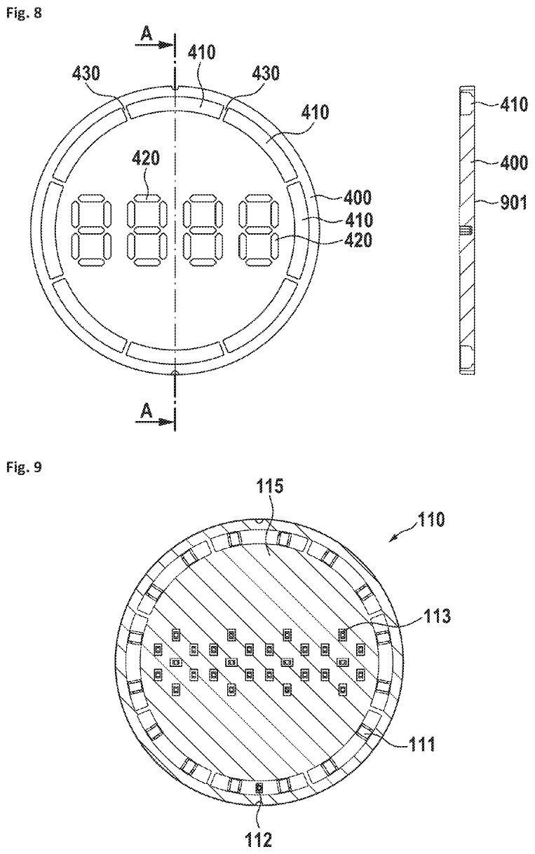

In FIG. 8, details of a cover disk 400 are shown in a front view as seen from the front side 901 at the left part of the figure. The right part of the figure shows a sectional view as marked by the letters A-A. The ring light channels 410 define a ring and the digit light channels 420 define digits and/or letter(s) and/or numbers. All light channels are separated by sidewalls 430.

In FIG. 9, a PCB 110 (printed circuit board) is shown in a top view from the front side. Here, ring LEDs 111 for illuminating the ring display 200 may be provided. Also, digit LEDs 113 for illuminating the digit display 300 may be provided. The digit LEDs may be smaller than the ring LEDs as they have to illuminate a smaller area and therefore need a smaller power. RGB LEDs may have a larger size than monochrome LEDs. There may be one or a plurality of photodiodes 112. Furthermore, a sensor area 115 may be provided. Preferably, this sensor area covers most of the surface of the PCB. The sensor area is coupled to a sensor circuit 120 and configured for evaluation of signals at the sensor area. The sensor circuit may detect the presence of a conductive object, for example a finger or a hand in close proximity to the sensor area. The term “close proximity” represents and defines a detection distance that, in related implementations, in preferably a range from 0 mm (when the conductive object is directly on or at the sensor area) to 30 mm above or away from the sensor area; or in a range from 0 mm to 10 mm, or from 0 mm to 5 mm. For detection an electric signal such as a HF or RF signal may be fed into the sensor area and changes in signal level by capacitive coupling to the object may be evaluated.

The sensor area may comprise multiple radially arranged sections. An inner section may be a main sensing section, while a surrounding section may be a guard or reference section. The inner section may cover the area within the ring LEDs 111, while the surrounding section may be the area outside the ring LEDs.

As shown in FIG. 4, a cover disk 400 is provided above the PCB 110. Therefore, the cover plate is between the object and the sensor area. The cover plate may comprise a dielectric material such as a plastic material. Such a dielectric material improves coupling of the electric field from the sensor area to the object. A further improvement may be made by using an electrically conductive cover plate. Such a cover plate may comprise a metal or a plastic body having a metallized surface. This cover plate may be electrically connected to the sensor area. In most cases capacitive coupling to the sensor area would be sufficient, as the cover plate may be arranged directly above the sensor area.

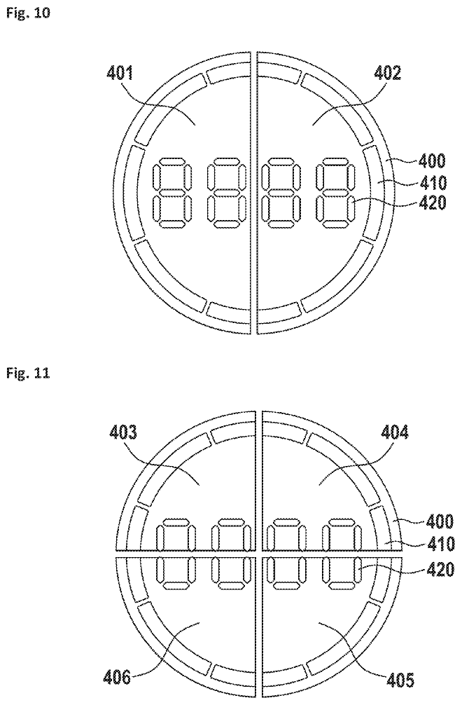

FIG. 10 illustrates a sectioned cover disk. Here, the cover disk is separated into two parts by a vertical separation forming a left section 401 and a right section 402. Such a sectioned cover disk serves to localize the presence of a finger or another object to a section. In this embodiment, it may be detected whether a finger is over the left section 401 or the right section 402. This and other similar embodiments may be combined with a radial arrangement as disclosed above.

In FIG. 11, a further sectioned cover disk comprising four sections is shown. In this embodiment, there is a horizontal and a vertical separation between the cover disks forming four equally shaped sections 403, 404, 405, and 406. It is obvious that there may be any other numbers of cover disk sections. Also, the shape may be varied according to the requirements.

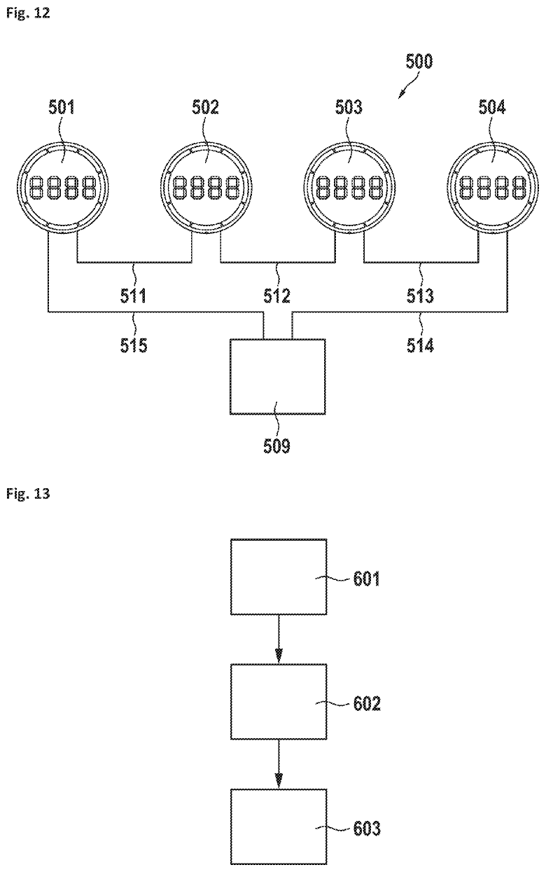

In FIG. 12, a consignment system 500 is shown. The consignment system comprises four capacitive sensor switches 501, 502, 503, and 504 together with a control unit 509. The capacitive sensor switches and the control unit are connected together by bus lines 511, 512, 513, 514, and 515 to a ring bus, such that they can communicate with each other.

In FIG. 13, a flow chart of a method of operating a consignment system is shown. In the first step 601, at least one capacitive sensor switch is assigned to a goods container, a tray, or a goods storage place. In the following step 602, the display of a capacitive sensor switch is controlled by a control unit to indicate the quantity of goods to be picked. In the following step 603, a signal to the control unit is generated to indicate that a capacitive sensor switch has been touched.

It will be appreciated to those skilled in the art having the benefit of this disclosure that this invention is believed to provide a capacitive sensor switch and an input and output unit for a consignment system. Further modifications and alternative embodiments of various aspects of the invention will be apparent to those skilled in the art in view of this description. Accordingly, this description is to be construed as illustrative only and is provided for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

### LIST OF REFERENCE NUMERALS

100 Sensor assembly
110 PCB (printed circuit board)
111 ring LED
112 photodiode
113 digit LED
115 sensor area
120 sensor circuit
200 ring display
210 LED
220 optical sensor
300 digit display
400 cover disk
401-406 disk sections
410 ring light channels
420 digit light channels
430 sidewalls
440 channel inner wall
450 channel edge
500 consignment system
501-504 capacitive sensor switches
509 control unit
511-515 bus lines
601-603 method steps
900 sensor switch
901 front side
902 rear side
910 housing
940 fixation means
951 first bus connector
952 second bus connector
955 first cable connector
956 second cable connector
980 casting compound

1. A capacitive sensor switch comprising:
a housing with a front side and a rear side, the sensor switch including a sensor assembly, wherein the sensor assembly further comprises:
a printed circuit board carrying a sensor circuit, a sensor area, and a plurality of LEDs, the sensor area being connected to the sensor circuit, and
a cover disk on the printed circuit board above the sensor area and oriented towards the front side
wherein:
the cover disk comprises a dielectric material,
the cover disk comprises a plurality of light channels through the cover disk, and
at least one of the LEDs is arranged within a light channel.

2. The capacitive sensor switch according to claim 1, wherein at least one light channel from the plurality of light channels penetrates the cover disk from the printed circuit board to the front side.

3. The capacitive sensor switch according to claim 1, wherein the cover disk comprises at least one sidewall between at least two light channels from the plurality of light channels.

4. The capacitive sensor switch according to claim 1, further comprising a ring display that includes multiple arc shaped segments, with each segment comprising at least one LED in a corresponding light channel.

5. The capacitive sensor switch according to claim 1, further comprising a digit display that includes multiple display segments arranged to form at least one of a digit and a letter, with each segment comprising at least one LED in a light channel.

6. The capacitive sensor switch according to claim 1, wherein at least one LED from the plurality of LEDs is positioned on the printed circuit board and in a light channel from the plurality of light channels.

7. The capacitive sensor switch according to claim 1, comprising at least one optical sensor on the printed circuit board and in a light channel from the plurality of light channels.

8. The capacitive sensor switch according to claim 7, wherein the at least one optical sensor is an optical proximity sensor.

9. The capacitive sensor switch according to claim 1, wherein at least one of the cover disk and the sensor area comprises multiple conductive sections that are insulated from each other and individually connected to the sensor circuit.

10. The capacitive sensor switch according to claim 1, wherein the sensor circuit has means for detecting at least one of a presence, a direction, a speed of movement of a conductive object in close proximity to at least one of i) at least one of an electrically conductive surface and an electrically conductive material connected to the sensor circuit, ii) the sensor area, and iii) an at least one optical sensor disposed on the printed circuit board and in a light channel from the plurality of light channels.

11. The capacitive sensor switch according to claim 1, further comprising a bus interface or a network interface.

12. The capacitive sensor switch according to claim 1, wherein the rear side comprises at least one fixation means or an additional sensor assembly.

13. A capacitive sensor switch comprising a housing with a front side and a rear side, the capacitive sensor switch including a sensor assembly, wherein the sensor assembly further comprises:
a printed circuit board including a sensor circuit and a plurality of LEDs, and
a cover disk disposed on the printed circuit board and oriented towards the front side,
wherein the cover disk comprises at least one of an electrically conductive surface and an electrically conductive material,
wherein the cover disk is capacitively coupled or galvanically connected to the sensor circuit, and
wherein the cover disk comprises a plurality of light channels through the cover disk and
at least one of the LEDs is arranged within a light channel from said plurality of light channels.

14. The capacitive sensor switch according to claim 13, wherein at least one light channel penetrates the cover disk from the printed circuit board to the front side.

15. The capacitive sensor switch according to claim 14, wherein the cover disk comprises at least one sidewall between at least two light channels from the plurality of light channels.

16. The capacitive sensor switch according to claim 14, further comprising a ring display that includes multiple arc shaped segments, wherein each segment contains at least one LED in a light channel from the plurality of light channels.

17. The capacitive sensor switch according to claim 14, further comprising a digit display that includes multiple display segments arranged to form at least a digit or a letter, with each segment comprising at least one LED in a light channel.

18. The capacitive sensor switch according to claim 14, wherein at least one LED is positioned on the printed circuit board and in a light channel.

19. The capacitive sensor switch according to claim 14, wherein at least one optical sensor is positioned on the printed circuit board and in a light channel.

20. The capacitive sensor switch according to claim 19, wherein

21. The capacitive sensor switch according to claim 13, wherein at least one of the cover disk and the sensor area comprises multiple conductive sections that are insulated from each other and individually connected to the sensor circuit.

22. The capacitive sensor switch according to claim 13, wherein the sensor circuit has means for detecting at least one of a presence, a direction, and a speed of movement of a conductive object located in close proximity to at least one of i) the electrically conductive surface, ii) an electrically conductive material connected to the sensor circuit; iii) the sensor area and iv) and optical sensor positioned on the printed circuit board and in a light channel.

23. The capacitive sensor switch according to claim 12, wherein the sensor switch comprises a bus interface or a network interface.

24. The capacitive sensor switch according to claim 12, wherein the rear side comprises at least one fixation means or the rear side comprises an additional sensor assembly.

25. A consignment system comprising a plurality of capacitive sensor switches, a control unit, and a digit display.

26. The consignment system according to claim 25, further comprising a ring display.

27. The consignment system according to claim 26, wherein the capacitive sensor switches are interconnected and further connected to the control unit by bus lines forming an operational network of bus lines.

28. The consignment system according to claim 27, wherein said network of bus lines is a ring network of bus lines.

29. A consignment system comprising a plurality of capacitive sensor switches according to claim 1, a control unit, and a digit display.

30. The consignment system according to claim 29, further comprising a ring display.

31. The consignment system according to claim 30, wherein the capacitive sensor switches are interconnected and further connected to the control unit by bus lines forming a bus line network.

32. The consignment system according to claim 31, wherein said bus line network is a ring network.

33. A consignment system comprising a plurality of capacitive sensor switches according to claim 13, with a digit display and an optional ring display and further comprising a control unit.

34. The consignment system according to claim 33, wherein the capacitive sensor switches are interconnected and further connected to the control unit by bus lines forming a network and preferably a ring network.

35. A method for operating a consignment system according to claim 25, comprising the steps of:
assigning at least one capacitive sensor switch to a goods container, a tray, or a goods storage place,
controlling displays of the plurality of capacitive sensor switches with the control unit to generate indicia of a quantity of goods to be picked,
transferring of a signal to the control unit, indicating that a capacitive sensor switch has been touched.
